(19) United States
(12) Patent Application Publication
(10) Pub. No.: US 2026/0223407 A1
(43) Pub. Date: Jul. 30, 2026

(54) THIN-FILM TRANSISTOR, DISPLAY PANEL AND DISPLAY DEVICE

(71) Applicant: Guangzhou China Star Optoelectronics Semiconductor Display Technology Co., LTd., Guangzhou (CN)

(72) Inventors: Xiaolin YAN, Guangzhou (CN); Jun ZHAO, Guangzhou (CN); Bin ZHAO, Guangzhou (CN); Juncheng XIAO, Guangzhou (CN); Jingdong Liu, Guangzhou (CN); Daobing HU, Guangzhou (CN)

(73) Assignee: Guangzhou China Star Optoelectronics Semiconductor Display Technology Co., LTd., Guangzhou (CN)

(21) Appl. No.: 19/224,786

(22) Filed: May 31, 2025

(30) Foreign Application Priority Data
Jan. 24, 2025 (CN) 202510122892.0

(51) Int. Cl. H10D 30/67; H10D 86/40

(52) U.S. Cl. CPC H10D 30/6755; H10D 30/6723; H10D 86/423

(57) ABSTRACT

A thin-film transistor, a display panel, and a display device are provided. The thin-film transistor includes an active layer and a gate disposed on a side of the active layer; a material of the active layer includes an oxide semiconductor material and a first metal element doped in the oxide semiconductor material, and the first metal element includes terbium.

### CROSS-REFERENCE TO RELATED APPLICATION

This application claims priority to and the benefit of Chinese Patent Application No. 202510122892.0, filed on Jan. 24, 2025, the disclosure of which is incorporated herein by reference in its entirety.

### TECHNICAL FIELD

The present disclosure relates to the field of display technology, and in particular, to a thin-film transistor, a display panel and a display device.

### BACKGROUND

With the increasing demand for high resolution, high definition, fast response, and low power consumption of display panels, oxide semiconductor thin-film transistor (OS TFT) is being increasingly applied in liquid crystal display (LCD) and organic light emitting diode (OLED) display panels due to their characteristics of high carrier mobility, low off-state leakage current, and high uniformity.

At present, with the increasing demand for large size and high resolution in the display industry, higher requirements are being placed on the mobility and stability of the oxide semiconductor. For large-size display panels, due to factors such as process instability and equipment parameter instability during the film forming process, the performance parameters of the oxide thin-film transistor exhibit significant variations, ultimately affecting the uniformity and stability of the oxide semiconductor thin-film transistor in the large-size display panel.

Therefore, it is necessary to provide a thin-film transistor, a display panel and a display device to address this defect.

### SUMMARY

The embodiments of the present disclosure provide a thin-film transistor, a display panel, and a display device, which can improve the uniformity and stability of the oxide thin-film transistor.

To achieve the above purpose, in a first aspect of the present disclosure, a thin-film transistor is provided, including:
an active layer; and
a gate disposed on a side of the active layer;
a material of the active layer includes an oxide semiconductor material and a first metal element doped in the oxide semiconductor material, and the first metal element includes terbium.

Optionally, a second metal element is further doped in the oxide semiconductor material, and the second metal element is in a positive tetravalent state;

Optionally, an atomic percentage of the first metal element is greater than 0% and less than or equal to 3%, and an atomic percentage of the second metal element is greater than 0% and less than or equal to 20%.

Optionally, the second metal element includes tin.

Optionally, the oxide semiconductor material includes an indium element and a gallium element;
an atomic percentage of the indium element is greater than or equal to 60% and less than or equal to 90%, and an atomic percentage of the gallium element is greater than or equal to 0% and less than or equal to 20%.

Optionally, a carrier concentration of the active layer is greater than or equal to 10¹⁹ cm⁻³ and less than or equal to 10²⁰ cm⁻³.

Optionally, a band gap of the active layer is greater than or equal to 3 eV and less than or equal to 3.8 eV.

Optionally, the active layer is configured in a crystalline state.

Optionally, the active layer is configured in a non-crystalline state.

Optionally, the thin-film transistor further includes a source and a drain, and the source and the drain are respectively connected to the active layer;
a current between the source and the drain is configured to be less than or equal to 10⁻¹⁰ A when no gate voltage is applied to the gate.

Optionally, the gate is disposed on a side of the active layer away from the source, or the gate is disposed on a side of the active layer close to the source.

In a second aspect of the present disclosure, a display panel is provided, including any one of the thin-film transistors as described above.

In a third aspect of the present disclosure, a display device is provided, including the display panel as described above.

In the thin-film transistor of the embodiments of the present disclosure, by doping the first metal element containing terbium element in the oxide semiconductor material in the active layer of the thin-film transistor, the heterostructure in the active layer is increased, and the crystallinity of the active layer is reduced, thereby improving the uniformity and stability of the thin-film transistor.

Other features and advantages of the present disclosure will be described in detail in the following detailed description.

### BRIEF DESCRIPTION OF THE DRAWINGS

In order to illustrate the technical solutions in the embodiments of the present disclosure more clearly, the drawings used in the description of the embodiments will be briefly introduced below. It is apparent that the drawings described below are only some embodiments of the present disclosure, and for those skilled in the art, other drawings can be obtained from these drawings without making creative efforts.

In order to fully understand the present disclosure and beneficial effects thereof, the description will be given below in conjunction with the drawings, and the same reference numerals in the description below indicate the same parts in the drawings.

FIG. 1 is a schematic diagram of a structure of a first display panel according to some embodiments of the present disclosure;

FIG. 2 is a schematic diagram of a structure of a second display panel according to some embodiments of the present disclosure;

FIG. 3 is a schematic diagram of a display device according to some embodiments of the present disclosure.

### DESCRIPTION OF THE REFERENCE NUMERALS

1. Display panel; 11. Substrate; 12. Thin-film transistor; 121 Active layer; 122. Gate; 123. Source; 124. Drain; 13. Gate insulating layer; 14. Passivation layer; 15. Light shielding layer; 16. Barrier layer; 17. Interlayer dielectric layer;
10. Display Device.

### DETAILED DESCRIPTION

The technical solutions in the embodiments of the present disclosure will be clearly and completely described below in conjunction with the accompanying drawings in the embodiments of the present disclosure. It is apparent that the embodiments described herein are only a portion of the embodiments of the present disclosure, but not all of the embodiments of the present disclosure. Based on the embodiments of the present disclosure, all other embodiments obtained by those skilled in the art without making creative efforts fall within the scope of protection of the present disclosure.

Embodiments of the present disclosure provide a thin-film transistor, the thin-film transistor includes an active layer and a gate, the gate is disposed on one side of the active layer, a material of the active layer includes an oxide semiconductor material and a first metal element doped in the oxide semiconductor material, and the first metal element includes terbium.

In the embodiments of the present disclosure, by doping the first metal element containing the terbium element in the oxide semiconductor material in the active layer of the thin-film transistor, the heterostructure in the active layer is increased, and the crystallinity of the active layer is reduced, thereby improving the uniformity and stability of the thin-film transistor.

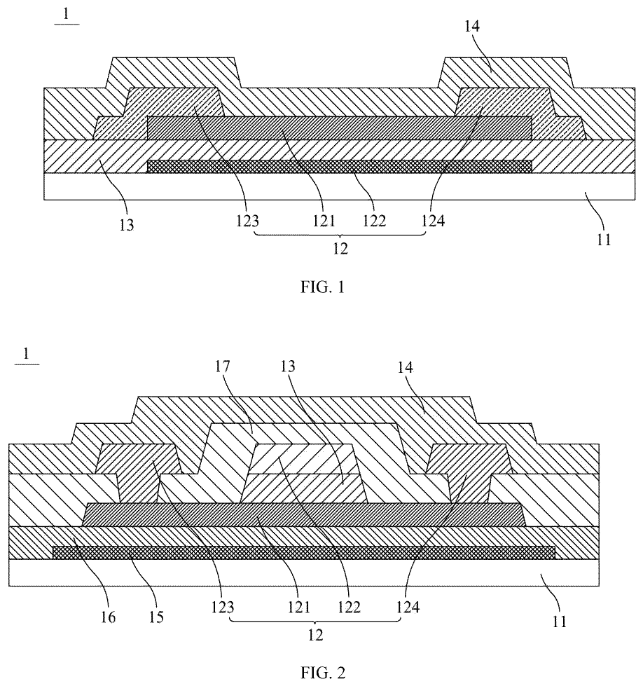

Referring to FIG. 1, and FIG. 1 is a schematic diagram of a structure of a first display panel according to some embodiments of the present disclosure. A thin-film transistor 12 is applied to a display panel 1, the display panel 1 includes a substrate 11 and the thin-film transistor 12, and the thin-film transistor 12 is disposed on the substrate 11. The thin-film transistor 12 includes an active layer 121, the material of the active layer 121 includes an oxide semiconductor material and a first metal element doped in the oxide semiconductor material, and the first metal element includes terbium (Tb).

In the embodiments of the present disclosure, by doping the first metal element containing terbium element in the oxide semiconductor material in the active layer 121 of the thin-film transistor 12, the heterostructure in the active layer 121 is increased, and the crystallinity of the active layer 121 is reduced, thereby improving the uniformity and stability of the thin-film transistor 12. In practical applications, other metal elements having the same effect as the terbium element can also be doped as the first metal element.

In some embodiments, referring to FIG. 1, a second metal element is further doped in the oxide semiconductor material of the active layer 121, and the second metal element includes tin (Sn). The tin element can provide carriers and passivate the defects of oxidation, and the terbium element can provide a recombination center for photo generated carriers to improve photostability. By doping both the tin element and the terbium element in the active layer 121, the heterostructure in the active layer 121 can be increased, the crystallinity of the active layer 121 can be reduced, and thereby improving the uniformity and stability of the thin-film transistor 12. In practical applications, other metal elements having the same effect as the tin element can also be doped as the second metal element.

In some embodiments, referring to FIG. 1, the atomic percentage of the second metal element in the active layer 121 is greater than 0% and less than or equal to 20%, and the atomic percentage of the first metal element is greater than 0% and less than or equal to 3%. For example, the atomic percentage of the tin element in the active layer 121 is 20%, and the atomic percentage of the terbium element is 1%. Alternatively, the atomic percentage of the tin element in the active layer 121 is 10%, and the atomic percentage of the terbium element is 2%. Alternatively, the atomic percentage of the tin element in the active layer 121 is 1%, and the atomic percentage of the terbium element is 3%.

In some embodiments, the active layer 121 is doped with the terbium element and is not doped with the tin element. That is, the atomic percentage of the tin element is 0%, and the atomic percentage of the terbium element is greater than or equal to 0% and less than or equal to 3%. In this way, the heterostructure in the active layer 121 can also be increased, and the crystallinity of the active layer 121 can be reduced, thereby improving the uniformity and stability of the thin-film transistor 12.

In some embodiments, the oxide semiconductor material includes the indium (In) element and gallium (Ga) element, the atomic percentage of the indium element is greater than or equal to 60% and less than or equal to 90%, and the atomic percentage of the gallium element is greater than or equal to 0% and less than or equal to 20%.

It should be noted that in the present embodiment, the oxide of the indium element accounts for a relatively high proportion as the host material of the active layer 121, so that the active layer 121 has a relatively large carrier concentration, resulting in a high mobility of the active layer 121. If the atomic percentage of the indium element in the active layer 121 is less than 60%, the mobility of the active layer 121 is low, which cannot meet the requirements. Further, the atomic percentage of the indium element is related to the crystalline state of the active layer. When the atomic percentage of the indium element is less than 80%, the active layer 121 is in a crystalline state, and when the atomic percentage of the indium element is greater than 80%, the active layer 121 is in a non-crystalline state. The proportion of the gallium element is relatively low, and the gallium element can be used as a carrier inhibitor, thereby reducing the oxygen vacancy in the active layer 121 and improving the stability of the active layer 121.

In some embodiments, the active layer 121 is provided with the indium element, the gallium element is completely replaced by the terbium element and/or the tin element, that is, the oxide semiconductor material is indium oxide, and the oxide of the indium element is used as the host material of the active layer 121. By doping the terbium element in the indium oxide, or doping both the tin element and terbium element in the indium oxide, the heterostructure in the active layer 121 can be increased, and the crystallinity of the active layer 121 can be reduced, thereby improving the uniformity and stability of the thin-film transistor 12.

In some embodiments, the indium element and gallium element are provided in the active layer 121, that is, the material of the active layer 121 is indium gallium oxide, the terbium element is doped in the indium gallium oxide, or the tin element and terbium element are both doped in the indium gallium oxide. The gallium element can be used as a carrier inhibitor to reduce the oxygen vacancy in the active layer 121, thereby improving the stability of the active layer 121. By doping the terbium element in the indium gallium oxide, or doping both the tin element and the terbium element in the indium gallium oxide, the heterostructure in the active layer 121 can be increased, and the crystallinity of the active layer 121 can be reduced, thereby improving the uniformity and stability of the thin-film transistor 12.

In some embodiments, a carrier concentration of the active layer 121 is greater than or equal to 10¹⁹ cm⁻³ and less than or equal to 10²⁰ cm⁻³. For example, the carrier concentration of the active layer 121 is 10¹⁹cm⁻³, or 10²⁰cm⁻³, and the like. It should be noted that the carrier concentration and mobility of the active layer 121 are positively correlated. The carrier concentration of the active layer 121 is limited to be between 10¹⁹ cm⁻³ and less than or equal to 10²⁰ cm⁻³, so that not only the active layer 121 can achieve higher mobility, but the switching characteristics of the thin-film transistor 12 can also be maintained, thereby avoiding situations where it is difficult to turn off the thin-film transistor 12.

In some embodiments, the band gap of the active layer 121 is greater than or equal to 3 eV and less than or equal to 3.8 eV. For example, the band gap of the active layer 121 is 3.2 eV, 3.4 eV, 3.6 eV, 3.8 eV, and the like.

It should be noted that if the band gap of the active layer is too low, the photostability of the active layer will be poor. If the band gap of the active layer is too high, the mobility of the active layer will deteriorate. In the embodiments of the present disclosure, by doping only the terbium element or both the terbium element and tin element in the active layer 121, the band gap of the active layer 121 can be limited to be between 3 eV and 3.8 eV, thereby improving the stability of the active layer while achieving mobility.

In some embodiments, the second metal element is in a positive tetravalent state. It should be noted that the tin ions in the positive tetravalent state used as donor doping can replace the cations in the active layer 121, and each tin ion in the positive tetravalent state can provide an additional free electron, so as to increase the number of electrons and forming N-type doping, thereby increasing the carrier concentration in the active layer 121. The tin ion in the positive tetravalent state cannot only reduce the lattice defect in the active layer 121 and reduce the electron scattering, but also reduce the impurity scattering, thereby further improving the mobility of the active layer 121.

In some embodiments, the active layer 121 is configured to be in a crystalline state, and by doping both the tin element and the terbium element in the active layer 121, the heterostructure in the active layer 121 can be increased, and the crystallinity of the active layer can be reduced, thereby improving the uniformity and stability of the thin-film transistor.

In some embodiments, the active layer 121 is configured to be in a non-crystalline state, the non-crystalline state is an amorphous state, and the mobility of the active layer 121 in the non-crystalline state increases as the carrier concentration increases. By increasing the carrier concentration of the active layer 121, the mobility of the active layer 121 can be improved.

In some embodiments, referring to FIG. 1, the thin-film transistor 12 includes a gate 122, a source 123, and a drain 124. The gate 122 is disposed in alignment with the active layer 121 along the film thickness direction of the gate 122, and the source 123 and the drain 124 are respectively connected to the active layer 121. When no gate voltage is applied to the gate 122, the current between the source 123 and the drain 124 is configured to be less than or equal to 10⁻¹⁰ A. By providing the current less than or equal to 10⁻¹⁰ A between the source 123 and the drain 124 when no gate voltage is applied, the off-state current of the thin-film transistor 12 can be reduced, thereby reducing the power consumption of the thin-film transistor 12.

In some embodiments, referring to FIG. 1, the thin-film transistor 12 has a bottom gate structure, and the gate 122 is disposed on the side of the active layer 121 close to the substrate 11.

In some embodiments, referring to FIG. 1, the display panel 1 further includes a gate insulating layer 13 and a passivation layer 14. The gate insulating layer 13 is disposed on the substrate 11 and the gate 122, the active layer 121 is disposed on the surface of the gate insulating layer 13 away from the substrate 11. The source 123 and the drain 124 are disposed on the active layer 121 and are respectively lap-connected to two opposite ends of the active layer 121. The passivation layer 14 is disposed on the source and the drain 124, and covers the active layer 121 and the gate insulating layer 13.

In some embodiments, referring to FIG. 2, and FIG. 2 is a schematic diagram of a structure of a second display panel according to some embodiments of the present disclosure, and the structure thereof is substantially the same as the structure of the thin-film transistor in the first display panel shown in FIG. 1, and the difference is that: the thin-film transistor 12 in the display panel shown in FIG. 2 has a top gate structure, and the gate 122 is disposed on the side of the active layer 121 away from the substrate 11. The display panel 1 further includes a light shielding layer 15, a barrier layer 16, a gate insulating layer 13, an interlayer dielectric layer 17, and a passivation layer 14. The light shielding layer 15 is disposed on the substrate 11, the barrier layer 16 is disposed on the substrate 11 and the light shielding layer 15, the active layer 121 is disposed on the surface of the barrier layer 16 away from the substrate 11, the gate insulating layer 13 is disposed on the surface of the active layer 121 away from the substrate 11, the gate 122 is disposed on the surface of the gate insulating layer 13 away from the active layer 121, and the interlayer dielectric layer 17 is disposed on the gate 122 and the active layer 121. The source 123 and the drain 124 are disposed on the interlayer dielectric layer 17, the source 123 and the drain 124 are respectively lap-connected to the active layer 121 through via holes in the interlayer dielectric layer 17, and the passivation layer 14 is disposed on the source 123, the drain 124, and the interlayer dielectric layer 17.

Referring to FIG. 1 and FIG. 2, it can be seen that the type of the thin-film transistor provided by the embodiments of the present disclosure may be a top gate structure or a bottom gate structure, and the thin-film transistor may also be a thin-film transistor of a back channel etching type or a thin-film transistor of a top gate self-aligned type. By doping the terbium or doping both the terbium and tin in the active layer of various types of thin-film transistors described above, the heterostructure in the active layer can be increased and the crystallinity of the active layer can be reduced, thereby improving the uniformity and stability of the thin-film transistor.

According to the thin-film transistor provided by the embodiments of the present disclosure, the embodiments of the present disclosure further provide a display panel. Referring to FIG. 2, the display panel includes the thin-film transistor provided by any one of the embodiments described above, and the display panel provided by the embodiments of the present disclosure can achieve the same technical effect as that of the thin-film transistor provided by any one of the embodiments described above, and which will not be described herein again.

In some embodiments, the display panel 1 is a liquid crystal display panel, the display panel includes an array substrate, an opposite substrate, and a liquid crystal layer (not shown in the figure). The opposite substrate is disposed opposite to the array substrate, the liquid crystal layer is disposed between the array substrate and the opposite substrate, and the array substrate includes a thin-film transistor. When a color film layer is disposed on the side of the opposite substrate, the opposite substrate may be regarded as a color film substrate.

In some embodiments, the display panel 1 is an organic light-emitting diode display panel or a micro light-emitting diode display panel. Specifically, the display panel may include an array substrate, a light-emitting device layer. The array substrate includes a thin-film transistor, the light-emitting device layer is disposed on the array substrate, the light-emitting device layer is provided with a plurality of light-emitting devices, and the light-emitting device may be an organic light-emitting diode or a micro light-emitting diode chip.

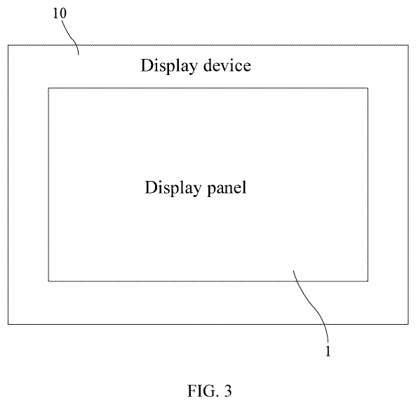

According to the display panel provided by the embodiments of the present disclosure, the embodiments of the present disclosure further provide a display device. Referring to FIG. 3, and FIG. 3 is a schematic diagram of a display device according to some embodiments of the present disclosure. The display device 10 includes a display panel 1, and the display panel 1 may be the display panel provided by any one of the embodiments described above. The display device provided by the embodiments of the present disclosure can achieve the same technical effect as that of the display panel provided by any one of the embodiments described above, and which will not be described herein again.

The beneficial effects of the embodiments of the present disclosure are as follows: the embodiments of the present disclosure provide a thin-film transistor, a display panel, and a display device. The thin-film transistor includes an active layer and a gate. By doping the first metal element containing terbium in the oxide semiconductor material of the active layer, the heterostructure in the active layer is increased, and the crystallinity of the active layer is reduced, thereby improving the uniformity and stability of the thin-film transistor.

In the description of the present disclosure, the terms “first”, “second” and the like are used for descriptive purposes only and are not to be construed as indicating or implying relative importance or implying an amount of indicated technical features. Thus, features defined with “first” and “second” may explicitly or implicitly include one or more of the features. In the description of the present disclosure, the term “a plurality of” refers to two or more unless otherwise specifically defined.

In the above embodiments, each embodiment is described with its own emphasis. For parts that are not described in detail in a certain embodiment, reference can be made to the relevant descriptions of other embodiments.

The embodiments, implementations and related technical features of the present disclosure can be combined and replaced with each other without conflict.

The above embodiments are merely preferred embodiments of the present disclosure, and do not limit the present disclosure in any form. Any simple modification, equivalent change and embellishment to the above embodiments based on the technical essence of the present disclosure without departing from the content of the technical solution of the present disclosure still fall within the scope of the technical solution of the present disclosure.

What is claimed is:

1. A thin-film transistor comprising:
an active layer; and
a gate disposed on a side of the active layer;
wherein a material of the active layer comprises an oxide semiconductor material and a first metal element doped in the oxide semiconductor material, and the first metal element comprises terbium.

2. The thin-film transistor according to claim 1, wherein a second metal element is further doped in the oxide semiconductor material, and the second metal element is in a positive tetravalent state.

3. The thin-film transistor according to claim 2, wherein an atomic percentage of the first metal element is greater than 0% and less than or equal to 3%, and an atomic percentage of the second metal element is greater than 0% and less than or equal to 20%.

4. The thin-film transistor according to claim 2, wherein the second metal element comprises tin.

5. The thin-film transistor according to claim 1, wherein the oxide semiconductor material comprises an indium element and a gallium element.

6. The thin-film transistor according to claim 5, wherein an atomic percentage of the indium element is greater than or equal to 60% and less than or equal to 90%, and an atomic percentage of the gallium element is greater than or equal to 0% and less than or equal to 20%.

7. The thin-film transistor according to claim 1, wherein a carrier concentration of the active layer is greater than or equal to 10¹⁹ cm⁻³ and less than or equal to 10²⁰ cm⁻³.

8. The thin-film transistor according to claim 1, wherein a band gap of the active layer is greater than or equal to 3 eV and less than or equal to 3.8 eV.

9. The thin-film transistor according to claim 1, wherein the active layer is in a crystalline state.

10. The thin-film transistor according to claim 1, wherein the active layer is in an non crystalline state.

11. The thin-film transistor according to claim 1, wherein the thin-film transistor further comprises a source and a drain, and the source and the drain are respectively connected to the active layer;
wherein a current between the source and the drain is configured to be less than or equal to 10⁻¹⁰ A when no gate voltage is applied to the gate.

12. The thin-film transistor according to claim 11, wherein the gate is disposed on a side of the active layer away from the source, or the gate is disposed on a side of the active layer close to the source.

13. A display panel comprising a thin-film transistor, wherein the thin-film transistor comprises:
an active layer; and
a gate disposed on a side of the active layer;
wherein a material of the active layer comprises an oxide semiconductor material and a first metal element doped in the oxide semiconductor material, and the first metal element comprises terbium.

14. The display panel according to claim 13, wherein a second metal element is further doped in the oxide semiconductor material, and the second metal element is in a positive tetravalent state.

15. The display panel according to claim 14, wherein an atomic percentage of the first metal element is greater than 0% and less than or equal to 3%, and an atomic percentage of the second metal element is greater than 0% and less than or equal to 20%.

16. The display panel according to claim 14, wherein the second metal element comprises tin.

17. The display panel according to claim 13, wherein the oxide semiconductor material comprises an indium element and a gallium element.

18. The display panel according to claim 17, wherein an atomic percentage of the indium element is greater than or equal to 60% and less than or equal to 90%, and an atomic percentage of the gallium element is greater than or equal to 0% and less than or equal to 20%.

19. The display panel according to claim 13, wherein a carrier concentration of the active layer is greater than or equal to 10¹⁹ cm⁻³ and less than or equal to 10²⁰ cm⁻³.

20. A display device comprising a display panel, wherein the display panel comprises a thin-film transistor, and the thin-film transistor comprises:
an active layer; and
a gate disposed on a side of the active layer;
wherein a material of the active layer comprises an oxide semiconductor material and a first metal element doped in the oxide semiconductor material, and the first metal element comprises terbium.
